(19) United States
(12) Patent Application Publication
(10) Pub. No.: US 2026/0099638 A1
(43) Pub. Date: Apr. 9, 2026

(54) MODELING APPROACH FOR DEVELOPMENT OF GAS INJECTION UNIT WITHIN PROCESSING CHAMBER

(71) Applicant: APPLIED MATERIALS, INC., Santa Clara, CA (US)

(72) Inventors: Devi Raghavee Veerappan, Eindhoven (NL); Balaji Devulapalli, Wildwood, MO (US); Shreeram Jyoti Dash, Newark, CA (US); Ajit Balakrishna, Santa Clara, CA (US); Alok Ranjan, San Ramon, CA (US)

(21) Appl. No.: 18/906,744

(22) Filed: Oct. 4, 2024

(51) Int. Cl. G06F 30/17

(52) U.S. Cl. CPC G06F 30/17

(57) ABSTRACT

A model of a processing chamber with a gas injection unit is used to perform simulated process conditions based on different combinations of parameter values. The simulated process conditions correspond to different measurements of a process variable, such as a etch byproduct removal rate. Based on the simulations, an optimal set of parameter values is determined that optimizes the variable. The gas injection unit is designed in accordance with this optimal set of parameter values.

### BACKGROUND

During substrate processing in semiconductor manufacturing, an etching process is used to create precise patterns on the substrate surface. This process, conducted within a controlled processing chamber, often generates byproducts as a result of chemical reactions between the etching gases and the substrate material. These byproducts, which can be gaseous, liquid, or solid, pose significant challenges to the etching process. For example, these byproducts can be re-deposited onto the substrate surface and can lead to several issues, including but not limited to non-uniform etching.

### BRIEF SUMMARY

In one aspect, a method includes generating a model of etch byproduct removal from a processing chamber includes a gas injection unit, where the model includes a plurality of adjustable parameters that correlate to an amount of the etch byproduct removal, performing simulations of a plurality of different sets of process conditions using the model, where each set of process conditions of the plurality of different sets of process conditions includes a different combination of parameter values for the plurality of adjustable parameters that correlate to the amount of the etch byproduct removal, determining measurements of etch byproduct removal rates for the simulations of the plurality of different sets of process conditions, determining, based on the measurements of etch byproduct removal rate, a first set of parameter values for the plurality of adjustable parameters corresponding to a first set of process conditions that maximize byproduct removal, and designing the gas injection unit in accordance with the first set of parameter values for the plurality of adjustable parameters.

In one aspect, a method includes configuring a model of a processing chamber includes a gas injection unit, where the model includes a plurality of adjustable parameters that correlate to a variable of the processing chamber, performing simulations of a plurality of different sets of process conditions using the model, where each set of process conditions of the plurality of different sets of process conditions includes a different combination of parameter values for the plurality of adjustable parameters, determining measurements of the variable for the simulations of the plurality of different sets of process conditions, determining, based on the measurements of the variable, a first set of parameter values for the plurality of adjustable parameters corresponding to a first set of process conditions that optimize the variable, and designing the gas injection unit in accordance with the first set of parameter values for the plurality of adjustable parameters.

In one aspect, a device includes a processor. The device also includes memory includes instructions that, upon being executed by the processor, cause the device to configure a model of a processing chamber includes a gas injection unit, where the model includes a plurality of adjustable parameters that correlate to a variable of the processing chamber, perform simulations of a plurality of different sets of process conditions using the model, where each set of process conditions of the plurality of different sets of process conditions includes a different combination of parameter values for the plurality of adjustable parameters, determine measurements of the variable for the simulations of the plurality of different sets of process conditions, and determine, based on the measurements of the variable, a first set of parameter values for the plurality of adjustable parameters corresponding to a first set of process conditions that optimize the variable, where the gas injection unit is designed in accordance with the first set of parameter values.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an aspect of the subject matter in accordance with one embodiment.

FIG. 2 illustrates a near wafer gas injection (NWGI) unit, according to one embodiment.

FIG. 3 illustrates a two-dimensional cross-section of a processing chamber with the NWGI unit, according to one embodiment.

FIG. 4 illustrates computational fluid dynamics (CFD) model of a processing chamber with a NWGI unit, according to one embodiment.

FIG. 5 is a flowchart of a method of optimizing a process variable, according to one embodiment.

FIG. 6 is a flowchart of a method of designing a gas injection unit to maximize an etch byproduct removal rate, according to one embodiment.

FIG. 7 is a flowchart of a method of designing a gas injection unit to optimize a process variable, according to one embodiment.

FIG. 8 illustrates an aspect of the subject matter in accordance with one embodiment.

### DETAILED DESCRIPTION

Technologies related to designing a near wafer gas injection (NWGI) unit of a processing chamber are described. Many different variables can influence the efficiency or quality of substrate production. Some of these variables may be controlled and accounted for by a NWGI unit. The NWGI unit may be placed near a circumference of a wafer (or other substrate) such that the NWGI unit disposes gas (e.g., such as a process gas) over the wafer during one or more steps of a process recipe. The NWGI unit may be designed to enhance control over certain variables, such as etching byproduct removal, ion flux impinging, or another extreme edge control (EEC) variable.

Etch byproduct may refer to residue or material created during an etching process of a process recipe. Etching steps may be used to manufacture integrated circuits (ICs). In some cases, during etching, reactive gases are used to selectively remove layers from a wafer to create the target patterns. The chemical reactions that occur during this process can produce various byproducts, including non-volatile compounds, particles, and other contaminants. These byproducts can accumulate on the wafer surface and/or in the etching chamber, potentially impacting the quality and performance of the final product. For example, byproducts redeposited back onto the wafer can lead to defects in the semiconductor devices, such as shorts, open circuits, or other electrical failures, which compromise the functionality and reliability of the final product. Redeposited byproducts can also interfere with subsequent processing steps, such as deposition or lithography, leading to further defects and yield loss.

Measuring byproduct removal in real time can be challenging due to the complex and dynamic nature of the etching process. The byproducts generated can vary in composition and form, making it difficult to develop a single measurement technique that can accurately detect all types of residues. Additionally, real-time monitoring may be based on highly sensitive and non-invasive methods that can operate in the harsh environment of the etching chamber without disrupting the process recipe. Conventional measurement techniques, such as optical emission spectroscopy or mass spectrometry, can provide some insights, but they often lack the resolution or specificity to detect and quantify all byproducts in real time.

Ion flux impinging can refer to the rate at which ions, typically generated in a plasma, strike or “impinge” on a surface during a semiconductor processing step, such as etching or deposition. In these processes, ions are accelerated towards the wafer surface by an electric field, where they either remove material (etching) or aid in the formation of thin films (deposition). A rate of ion flux impinging may directly influence the rate and uniformity of material removal or deposition on the wafer. Greater control over the ion flux impinging rate can generally lead to improved overall process efficiency and uniformity across the wafer. Excessive ion flux can lead to excessive etching and damage to the underlying layers of the wafer. Excessive ion flux can also cause undesired etching in non-target areas of the wafer. Conversely, if the ion flux is too low, the process recipe may be too slow. In cases where deposition or etching steps of a process recipe are timed, incomplete etching/deposition may occur, which can lead to wafer defects and yield loss.

Measuring the ion flux impinging rate in real time can be challenging due to the highly dynamic and complex environment within the plasma processing chamber. The ion flux impinging rate can vary rapidly depending on variables like plasma density, pressure, and electric field strength. These rapid changes within the processing chamber can be hard to measure using conventional measurement techniques. Additionally, any measurement tool used to measure the ion flux impinging rate should be non-invasive to avoid disturbing the plasma or affecting the wafer surface, which limits the types of sensors and techniques that can be used.

Extreme Edge Control (EEC) refers to the precise management of the etching or deposition process at the extreme edges of a semiconductor wafer. The wafer edge can often experience different conditions compared to the central regions of the wafer, such as variations in ion flux, temperature, and gas distribution. EEC aims to ensure that the edge of the wafer is processed uniformly, preventing defects like edge bead buildup, uneven material removal, or contamination that could propagate into the active device area of the wafer, which could potentially lead to yield loss and device failures. Poor control at the wafer edge can result in issues like inconsistent layer thickness (non-uniformity), contamination, and mechanical stress, which can affect the reliability and performance of products or devices manufactured on the wafer. As such, EEC variables include, but are not limited to, edge layer thickness, edge contamination, wafer mechanical stress, edge temperature, edge bead buildup, or the like.

Achieving EEC is difficult because the edge of the wafer presents unique challenges compared to the central region. The physical curvature of the edge, along with differences in local gas flow, ion flux, and temperature, can lead to non-uniform processing. Moreover, the wafer edge is less accessible for traditional monitoring and control tools, making it harder to achieve real-time adjustments.

Aspects and embodiments of the present disclosure address the problems described above and others by providing systems and methods of designing processing chambers and/or processing chamber components based on one or more process variables that are difficult to measure in real time. For example, understanding possible byproduct concentrations during etching can facilitate better design of processing chambers and their components, as it can enable more efficient and effective byproduct removal.

Aspects and embodiments of the present disclosure provide systems and method of designing an NWGI unit using a model with adjustable parameters. These adjustable parameters may correlate to one or more process variables, including but not limited to those described above (e.g., byproduct removal rate, ion flux impinging rate, EEC, or the like). These process variables may be difficult or impossible to measure or quantify in real time using conventional measurement tool approaches or techniques. Aspects and embodiments of the present disclosure may include performing simulations of different process conditions using the model. Each of the sets of process conditions may include a different combination of parameter values of the adjustable parameters. These adjustable parameters may include, but are not limited to, a number of orifices of the NWGI unit, diameter(s) of these orifices of the NWGI unit, a center flow rate of the processing chamber, an edge flow rate of the processing chamber, an NWGI flow rate, a distance(s) between the NWGI unit and the wafer, a height difference between the NWGI unit and the wafer, an atmospheric pressure within the processing chamber, an angle from which the NWGI unit is to direct gas onto the wafer, a timing synchronization, or the like.

Aspects and embodiments of the present disclosure optimize the process variable based on these simulations. Each simulation may output a different measured value of the process variable. Based on these measured values and their corresponding process conditions, aspects and embodiments of the present disclosure can determine optimal parameter values (e.g., first set of parameter values) for the process variable. These optimal parameter values may include only a subset of the adjustable parameters that are most sensitive to the process variable. The NWGI unit can then be designed based on these optimal parameter values.

The figures and accompanying illustrations below provide systems and methods of how the NWGI unit may be designed to increase control over byproduct removal rate during an etching process of a process recipe. One will appreciate that these systems and methods can be used to design the NWGI unit to increase control over different process variables, including but not limited to EEC or the ion flux impinging rate as described above.

Some embodiments are discussed herein with reference to design of an NWGI unit for use in a process chamber that processes wafers. However, it should be understood that the embodiments discussed with reference to wafers also apply to design of an NWGI unit used to process other types of substrates, such as display substrates (e.g., glass plates), photovoltaic substrates, and so on. Additionally, it should be understood that the embodiments discussed herein with reference to design of an NWGI unit also apply to design of other types of chamber components used in a process chamber, such as a showerhead, chamber interior (e.g., chamber lid, walls, floor, etc.), substrate support, and so on.

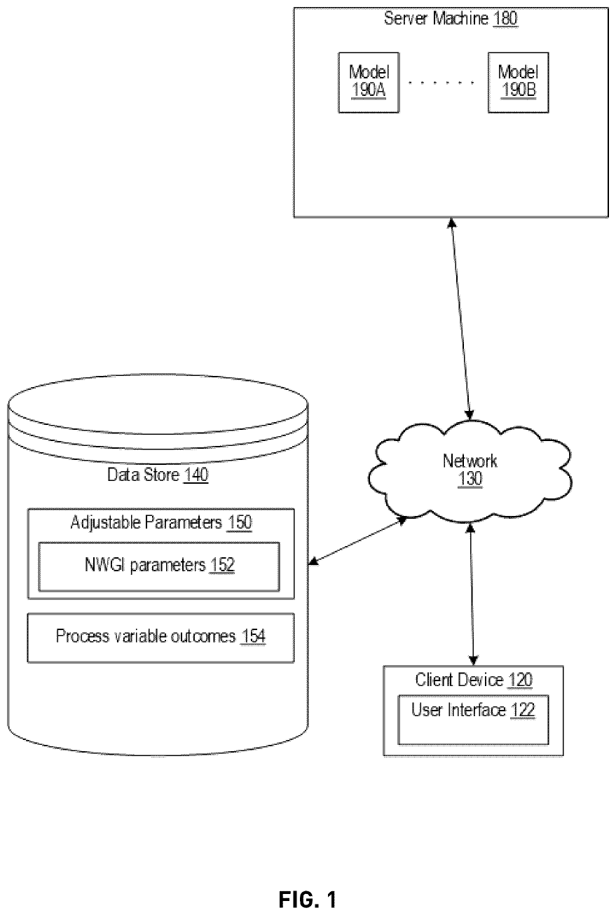

FIG. 1 is a block diagram illustrating an exemplary system 100 (exemplary system architecture) configured to design a near wafer gas injection (NWGI) unit, according to certain embodiments. The system 100 includes a client device 120, a data store 140, and a server machine 180.

In embodiments, data store 140 stores adjustable parameters 150. Data store 140 may be a memory (e.g., random access memory), a drive (e.g., a hard drive, a flash drive), a database system, or another type of component or device capable of storing data. Data store 140 may include multiple storage components (e.g., multiple drives or multiple databases) that may span multiple computing devices (e.g., multiple server computers). The data store 140 may store at least adjustable parameters 150 and process variable outcomes 154.

The adjustable parameters 150 may include any parameter related to a process recipe (e.g., a recipe that, upon being executed, produces a product or products over a period of time) and/or the NWGI (and/or another chamber component) that can be adjusted. Some of these parameters may be specific to the NWGI unit (i.e., NWGI parameters 152), and may be associated with a physical design of the NWGI unit. Other parameters may be controlled by other components or parts of a process chamber. As such, the adjustable parameters 150 can include one or more of a number of orifices of the NWGI unit, diameter(s) of these orifices of the NWGI unit, a center flow rate of the processing chamber, an edge flow rate of the processing chamber, an NWGI flow rate, a distance(s) between the NWGI unit and the wafer, a height difference between the NWGI unit and the wafer, an atmospheric pressure within the processing chamber, an angle from which the NWGI unit is to direct gas onto the wafer, a timing synchronization, gas composition (edge gas flow compared to center gas flow, percentages of inert and process gases), temperature (e.g., heater temperature), spacing (SP), pressure, High Frequency Radio Frequency (HFRF), radio frequency (RF) match voltage, RF match current, RF match capacitor position, voltage of Electrostatic Chuck (ESC), actuator position, electrical current, other flow parameters, power, voltage, or the like. In some embodiments, the data store 140 may store different sets of parameters values of the adjustable parameters 150. Each of these different sets of parameters values may correspond to different process conditions. Here, “process conditions” may refer to characteristics or conditions of the processing chamber that are caused by a combination of parameter values of the adjustable parameters 150. These process conditions may include but are not limited to temperature, pressure, gas flow rates, power input, and/or chemical concentrations.

The data store 140 may also store process variable outcomes 154. Each process variable outcome 154 may correspond to one of the sets of parameters values of the adjustable parameters 150. In some embodiments, the sets of parameters values may be inputted into a model (model(s) 190) to generate the process variable outcomes 154. These process variable outcomes 154 may be variable(s) or process condition(s) of which the model is designed to capture. For example, process variable outcomes 154 can include one or more of a byproduct removal rate, an ion flux impinging rate, or another variable for which the model is designed to measure or predict.

In some embodiments, one or more models 190A-N (referred to collectively as models 190) are executed on server machine 180. The server machine 180 can include a training engine, a validation engine, selection engine, and/or a testing engine. An engine (e.g., training engine, a validation engine, selection engine, and a testing engine) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine may be capable of training one or more of the model(s) 190.

In some embodiments, the model(s) 190 may include a physics-based digital twin model. The physics-based digital twin model may be capable of solving systems of equations describing physical phenomena that may occur in the manufacturing chamber, such as equations governing heat flow, energy balance, gas conductance, mass balance, fluid dynamics, or the like. The physics-based digital twin model may have been trained on data from a healthy or optimal chamber. A chamber having a healthy or optimal state may be expected to produce measured sensor readings that approximately match simulated sensor readings of the trained digital twin model.

Historical data, including historical sensor data and historical manufacturing parameters, may be used to train the physics-based model. In some embodiments, the physics-based model can capture the majority of physical phenomena that may occur in the manufacturing chamber before training, but some aspects may not be described by the physics-based model. Such aspects may include aging or non-ideal components, manufacturing tolerance or manufacturing inaccuracy induced variation, incomplete description of the chamber, or the like. By providing historical data to the physics-based model, parameters in the model may be adjusted to account for these inaccuracies.

Adjustable parameters 150 may be provided to the trained physics-based digital twin model. In some embodiments, the physics-based digital twin model performs calculations based on the inputted set of parameters values to determine an etch byproduct removal rate within the processing chamber. In at least one embodiment, the physics-based digital twin model can perform calculations of gas conductance in the manufacturing chamber. The trained physics-based model may provide as output modeled property value(s) indicative of conditions within the chamber, such as the etch byproduct removal rate. These output modeled property value(s) may be referred to as process variable outcome 154, which can be stored in the data store 140.

Use of a physics-based digital twin model in connection with manufacturing equipment such as a processing chamber can have significant technical advantages compared to operating manufacturing equipment without such a model. Using a physics-based digital twin model in connection with a processing chamber can facilitate a design process of the processing chamber or components of the processing chamber (e.g., of an NWGI) that are to provide greater control over hard-to-measure process conditions or variables, such as etch byproduct removal rate, EEC, ion flux impinging rate, or the like.

In some embodiments, the model(s) 190 may include a mathematical model such as a computational fluid dynamics (CFD) model. The CFD model and/or other mathematical model may be used to simulate and analyze a flow of materials (such as etch byproduct removal) within a confined space such as a processing chamber based on the adjustable parameters 150.

Creating the CFD model for a processing chamber may involve several different steps. First, a geometry of the processing chamber is defined, which includes detailing the chamber's dimensions, inlet and outlet locations, and any internal components that may influence fluid flow. This geometry can be created using CAD (Computer-Aided Design) software and then imported into a CFD simulation environment. Once the geometry is set, the space within the processing chamber is discretized, meaning that the volume of the processing chamber is divided into a mesh of small, finite elements. The quality and density of this mesh determine the accuracy of the simulation; for example, a finer mesh provides more detailed results but uses more computational resources. After setting up the geometry and mesh, boundary conditions and initial conditions can be specified. This involves defining process conditions such as inlet velocities, temperature profiles, pressure levels, and the properties of the working fluid (e.g., gas type, viscosity, and thermal conductivity). The process conditions may be defined using a set of parameter values of the adjustable parameters 150. Once all parameters are set, the CFD simulation is run, which can typically include iterative solving of the governing fluid dynamics equations. Post-processing tools may then be used to analyze the results, allowing engineers or other users to visualize fluid flow patterns, temperature distributions, and other key factors within the chamber.

Adjustable parameters 150 may be provided to the CFD model. In some embodiments, the CFD model performs calculations based on the inputted set of parameter values to determine an etch byproduct removal rate within the processing chamber. In at least one embodiment, the CFD model can perform calculations of gas conductance in the manufacturing chamber. The CFD model may provide as output modeled property value(s) indicative of conditions within the processing chamber, such as the etch byproduct removal rate. These output modeled property value(s) may be referred to as process variable outcomes 154, which can be stored in the data store 140.

While the above description provides examples of a physics-based digital twin model and a CFD model, the model(s) 190 may include any model(s) that are capable of simulating process conditions within a processing chamber. These can include, but are not limited to, a finite element analysis (FEA) model, a molecular dynamics (MD) model, a kinetic Monte Carlo (KMC) model, a plasma simulation model, a chemical reaction kinetics model, or any other physics-based modelling approach. In some embodiments, the various models discussed in connection with model 190 may be combined in one model (e.g., an ensemble model), or may be separate models. Data may be passed back and forth between several distinct models included in model(s) 190. In some embodiments, some or all of these operations may instead be performed by a different device, e.g., client device 120, server machine 180, or another device. It will be understood by one of ordinary skill in the art that variations in data flow, which components perform which processes, which models are provided with which data, and the like are within the scope of this disclosure.

Server machine 180, client device 120 and data store 140 may be connected via network 130. In some embodiments, network 130 is a public network that provides client device 120 with access to one or more of the server machine 180, data store 140, and/or other publicly available computing devices. In some embodiments, network 130 is a private network that provides client device 120 access to one or more of the server machine 180, data store 140, manufacturing equipment such as processing chamber(s) or mainframe(s), and/or other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

The client device 120 may include a computing device such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. The client device 120 may include a user interface 122. User interface 122 may receive user input (e.g., via a Graphical User Interface (GUI) displayed via the client device 120) of an indication of (e.g., a user input for) the adjustable parameters 150 and/or process variable outcomes 154 generated by the model(s) 190. In some embodiments, the user interface 122 may cause the NWGI unit to be designed in accordance with the process variable outcomes 154 produced over iterations of simulations using the model(s) 190 and the different sets of parameter values of the adjustable parameters 150. In some embodiments, the user interface 122 receives, from a user (e.g., an engineer), the different sets of parameter values of the adjustable parameter 150 based on a design of experiments (DoE). In at least one embodiment, the user interface 122 may receive ranges of values for each of the adjustable parameters 150, and generate different sets of parameter values based on those specified ranges. After the simulations are performed by the model(s) 190, in some embodiments, the user interface 122 obtains the process variable outcomes 154 and provides them to the user. Each client device 120 may include an operating system that allows users to one or more of generate, view, or edit data (e.g., the adjustable parameters 150, the process variable outcomes 154, or the like).

In general, a DoE is a systematic approach used to plan, conduct, analyze, and interpret controlled tests with the objective of evaluating the factors that may influence a particular outcome or process. Here, “experiments” can refer to each simulation of process conditions performed based on one set of parameter values of the adjustable parameters 150. The DoE is to identify cause-and-effect relationships efficiently. By selecting the input variables (here, the adjustable parameters 150) and their levels, and then systematically varying them according to a predefined plan, DoE allows for the examination of multiple factors simultaneously. This approach not only saves time and resources but also provides a comprehensive understanding of how factors interact with each other. The results from a DoE can lead to more robust processes and products, as they help in identifying the optimal settings of factors that lead to the target outcome, while also highlighting the factors that have minimal or no impact on the response.

In at least one embodiment, the sets of parameter values are generated based on a DoE with a space-filling design. A DoE with a space-filling design is used to thoroughly explore a design space. Here, each adjustable parameter may be given a range of parameter values (e.g., orifices having range of possible diameters from 1 millimeter (mm) to 20 mm). Unlike traditional factorial or fractional factorial designs that focus on a specific set of factor levels, space-filling designs aim to spread the experimental points evenly throughout the entire experimental region (i.e., the ranges of parameter values). In a space-filling design, the experimental points (i.e., the sets of parameter values of the adjustable parameters 150) are selected to “fill” the space, meaning they are placed in such a way that they cover the entire range of possible values for the input factors. This provides a more global perspective of the system being studied (i.e., the model(s) 190 of the processing chamber and NWGI unit), making it easier to identify regions of interest, such as areas (i.e., adjustable parameters 150) where the response is highly sensitive to changes in input factors. Examples of space-filling designs include Latin Hypercube designs, Sobol sequences, and Uniform designs. Any of these types of space-filling designs may be used to determine the sets of parameter values of the adjustable parameters 150.

The server machine 180 may include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), or the like.

In some embodiments, the model(s) 190 may include a machine learning model that is used to determine an optimal set of parameter values (e.g., the first set of parameter values) of the adjustable parameters 150. The machine learning model may be trained using the sets of parameter values of the adjustable parameters 150 as inputs and the process variable outcomes 154 as target outputs. Once trained, the machine learning model may be used to determine the optimal set of parameter values to enhance control of the designed-for process variable, such as the byproduct removal rate. For example, the machine learning model may be used to identify patterns between the data input (sets of parameters values of the adjustable parameter 150) and the target output (the correct answer, process variable outcomes 154), and the machine learning model is provided mappings that captures these patterns. The machine learning model 190 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network), or the like.

One type of machine learning model that may be used to perform some or all of the tasks described herein is an artificial neural network, such as a deep neural network. Artificial neural networks generally include a feature representation component with a classifier or regression layers that map features to a target output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., teeth, lips, gums, etc.); and the fourth layer may recognize a scanning role. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

For purpose of illustration, rather than limitation, aspects of the disclosure describe determining the optimal set of parameter values of the adjustable parameters 150 by simulating one or more sets of conditions using one or more of the model(s) 190 configured with the sets of parameter values of the adjustable parameters 150. The models may output the process variable outcome 154 associated with each set of conditions (e.g., set of parameter values). These process variable outcomes 154 may be compared to target process variable outcomes to determine an optimal design of a chamber component (e.g., of an NWGI). In other embodiments, a heuristic model or rule-based model can be used to determine the optimal set of parameter values of the adjustable parameters 150 (e.g., without using a machine learning model).

In some embodiments, the functions of client device 120 and server machine 180 may be provided by a fewer number of machines. For example, in some embodiments, server machine 180, the client device 120, and/or the data store 140 may be integrated into a single machine.

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

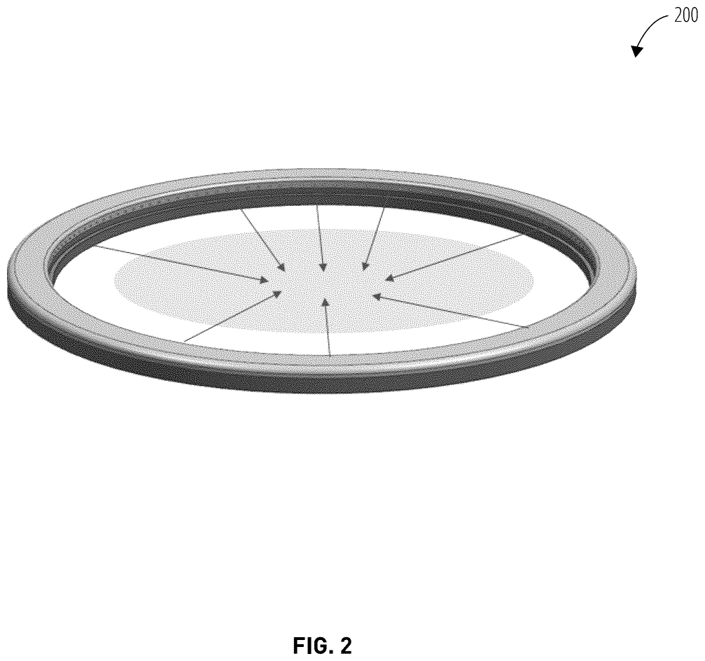

FIG. 2 illustrates a near wafer gas injection (NWGI) unit 200, according to one embodiment. In some embodiments, the NWGI unit 200 may have a cylindrical or ring shape with multiple orifices positioned to inject gas onto a wafer (or other substrate product). These orifices may be openings on an inner portion of the NWGI unit 200, such as nozzles, adjustable vents, pores, or another type of opening. In some embodiments, these orifices may be designed to direct gas flow over the substrate at a predetermined velocity. This predetermined velocity may facilitate byproduct removal during the etching process of a process recipe. This predetermined velocity may be less than a velocity that could potentially cause shockwave formations close to the wafer edge. In at least one embodiment, the NWGI unit 200 may be designed to have an inner circumference larger than the circumference of a wafer. In other words, the NWGI unit 200 may be designed to inject gas at or near the edge of the wafer. In one embodiment the NWGI unit 200 may be configured to encompass the wafer such that gas is uniformly directed onto the wafer via the orifices in a cylindrical manner. In other embodiments, the NWGI unit 200 may be configured to cause the gas to be directed onto the wafer in a non-uniform manner, such as a uni-directional flow.

As described above in FIG. 1, the system 100 may be used to design the NWGI unit 200 by performing simulations using a model of a processing chamber with the NWGI unit 200. Each of these simulations may have a different set of parameter values of the adjustable parameters 150. Each of these different sets of parameter values may have a different combination of parameter values. The adjustable parameters 150 may include NWGI parameters 152. These NWGI parameters 152 may include parameters of the NWGI unit 200 that are adjustable within the model. These NWGI parameters 152 can include, but are not limited to, physical parameters of the NWGI unit 200 (e.g., height, width, radius, or the like), a shape of the NWGI unit 200 (e.g., cylindrical, spherical, rectangular, or the like) a volumetric (or mass) flow rate of gas from the NWGI unit 200 (e.g., NWGI flow rate), a number of orifices directing gas flow onto the wafer, a size (e.g., diameter) of each of the orifices, an angle at which the orifices direct gas flow onto the wafer, or the like.

The simulations may be performed by the model(s) 190 using different parameter values for each of these NWGI parameters 152. For example, a first simulation may be performed using a first set of parameter values having a first number of orifices, the orifices having a first diameter length, a first NWGI flow rate, and a first angle at which the orifices direct gas flow onto the wafer. The first simulation may output a first process variable outcome 154 (e.g., a first byproduct removal rate). A second simulation may be performed using a second set of parameter values having a second number of orifices, the orifices having a second diameter length, a second NWGI flow rate, and a second angle at which the orifices direct gas flow onto the wafer. The second simulation may output a second process variable outcome 154 (e.g., a second byproduct removal rate). While these first and second sets of parameter values are different, they may overlap. For example, the first and second numbers of orifices may be different, but the first and second diameters, the first and second NWGI flow rates, and the first and second angles may be the same. In at least one embodiment, simulating having sets of parameter values that partially overlap can help determine relationships between each of the NWGI parameters 152 (or, more broadly, adjustable parameters 150) and the byproduct removal rate (or, more broadly, the designed-for process variable, whether it be the byproduct removal rate, the ion flux impinging rate, or another process variable). Performing simulations with partially overlapping sets of parameter values can also help determine relationships between NWGI parameters 152. As described above, each of these simulations generates a process variable outcome 154 that described how the designed-for process variable is affected by the corresponding set of parameter values.

These process variable outcomes 154, along with the sets of parameter values of the adjustable parameters 150 (which includes the NWGI parameters 152), are used to determine a set of optimal parameter values (the first set of parameters values) for the process variable. For example, if the process variable is the byproduct removal rate, the process variable outcomes 154 and adjustable parameters 150 are used to determine a set of parameter values that maximizes the byproduct removal rate. This can be done in various ways, including using a machine learning model. Once this machine learning model is trained, sets of parameter values corresponding to the adjustable parameters 150 can be inputted into the trained model. The ML model may output process variable outcomes associated with adjustable parameters based on an input comprising the adjustable parameters. In another example, an ML model may receive target process variable outcomes, and may output optimal parameter values for each of the adjustable parameters 150 that will achieve the target process variable outcomes.

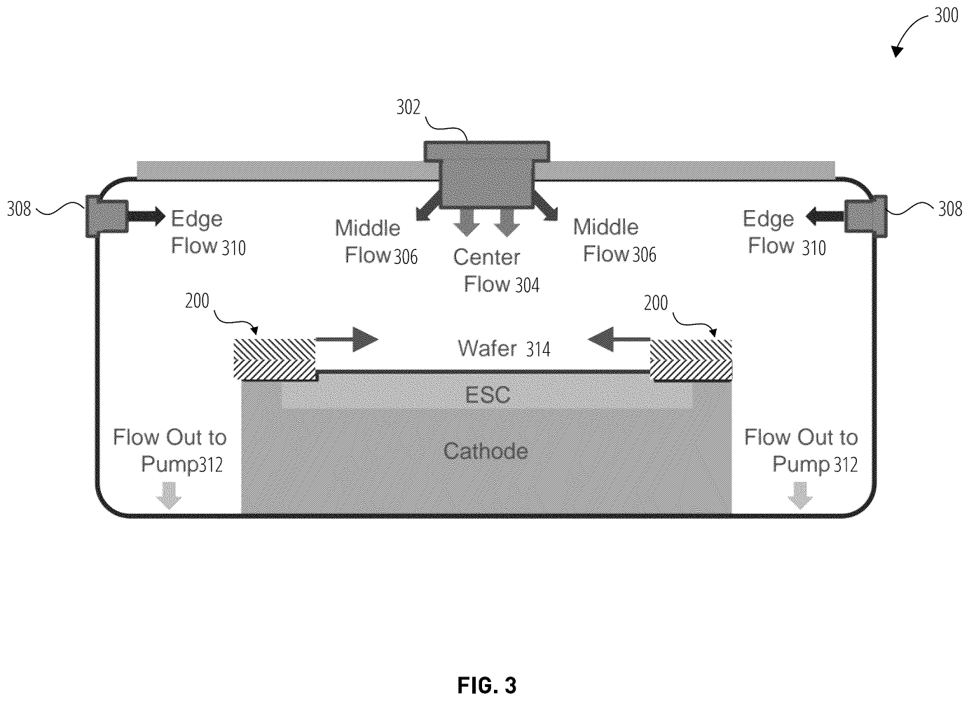

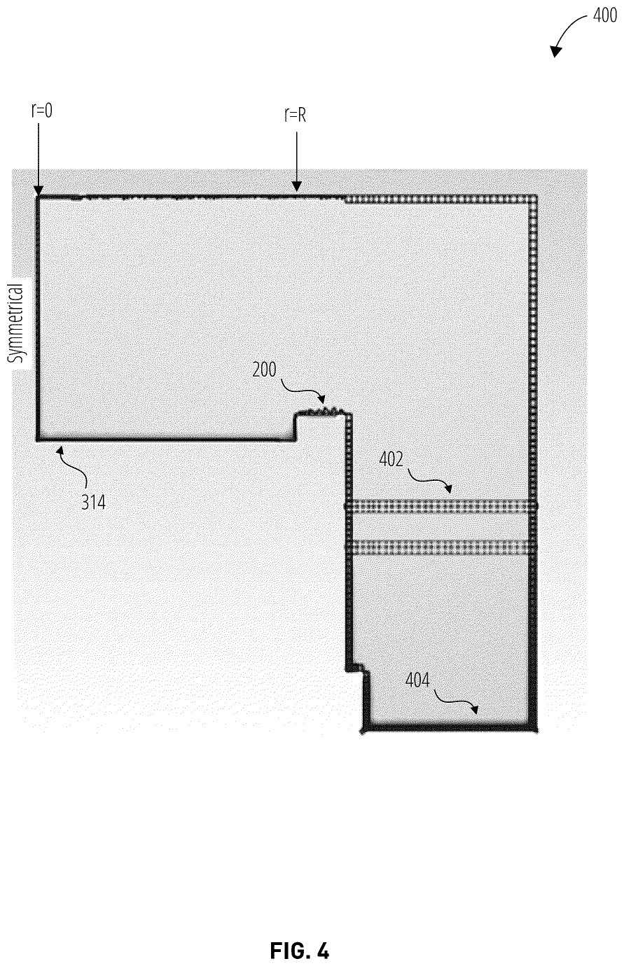

FIG. 3 illustrates a two-dimensional cross-section of a processing chamber 300 with the NWGI unit 200, according to one embodiment. The processing chamber 300 may include a showerhead 302, edge gas injectors 308, and the NWGI unit 200. Center and middle flows 304, 306 may be outputted by the showerhead 302, while edge flow 310 may be outputted by the edge gas injectors 308. In at least one embodiment, the adjustable parameters of model(s) described herein (e.g., adjustable parameters 150) may include these center, middle, and edge flows 304, 306, 310. As such, rates of these flows may be adjustable within the models described herein. Illustrated in FIG. 3 is also where gas is to flow from the processing chamber 300 to external flow out pump(s) 312, according to embodiments. The adjustable parameters may also include rates at which gas is to flow out to the flow out pump(s) 312. The processing chamber 300 may also include a wafer 314 positioned within the NWGI unit 200. The NWGI unit 200 may be positioned such that orifices on the NWGI unit 200 direct gas flow (e.g., NWGI gas flow) directly onto or above the wafer. FIG. 4 illustrates computational fluid dynamics (CFD) model 400 of a portion (e.g., half) of a processing chamber 300 with a NWGI unit 200, according to one embodiment. Creating the CFD model 400 may involve several different steps. First, the geometry of the chamber is defined. This involves creating a detailed 3D model that captures precise dimensions and features of the processing chamber (or portion thereof), including inlets (e.g., showerhead 302, edge gas injector 304, NWGI unit 200), outlets 404, and any internal structures such as baffles, heaters, plasma screens 402, or the like. One or more of the adjustable parameters 150 may correspond to this geometry. In other words, the CFD model 400 may include an adjustable geometry or multiple different CFD models each having a different geometry. In embodiments where the processing chamber 300 is symmetrical, the CFD model 400 may be designed for half of the process chamber to save computational resources.

Once the geometry is defined, the next step (i.e., the next process to perform) is to discretize the chamber into a mesh. The mesh divides the entire volume of the chamber into small, finite elements where the fluid flow equations will be solved. The quality and resolution of the mesh directly affect the accuracy of the simulation. A finer mesh can capture more details but will require more computational resources. Adaptive meshing techniques might be employed to refine the mesh in areas where gradients of variables like velocity, temperature, or species concentration are expected to be steeper.

After meshing, the physical models and boundary conditions are defined. This includes specifying the type of fluid (e.g., gas, plasma), its properties (such as viscosity, density), and any reactions that might occur within the chamber, such as the production of byproducts during the etching process of a process recipe. Boundary conditions are applied to define how the fluid enters and exits the chamber, as well as any heat transfer, surface reactions, or wall interactions that could affect the fluid flow. For example, the inlet might have a specified flow rate or pressure, and walls might be assigned a certain temperature or roughness. One or more of the adjustable parameters 150 may correspond to the physical models or boundary conditions. In other words, the CFD model 400 may have an adjustable physical model and/or adjustable boundary conditions, or multiple CFD models with different physical models and/or boundary conditions.

With the physical model and boundary conditions set, CFD simulation(s) can then be run. This can involve solving Navier-Stokes equations, which govern fluid motion, along with any additional equations for heat transfer, chemical reactions, or turbulence modeling. Depending on the complexity of the chamber and the physics involved, this process can be computationally intensive, often requiring high-performance computing resources to achieve a solution in a reasonable timeframe.

Once the simulation is complete, the results may be analyzed and validated. This process can involve interpreting the data, such as velocity fields, temperature distributions, and species concentrations, to understand the fluid behavior within the chamber. Validation against experimental data may be performed to ensure the model accurately represents real-world conditions. If discrepancies are found, the model may be refined, potentially involving adjustments to the mesh, boundary conditions, or physical models.

Once the CFD model 400 has been analyzed and validated, a user (e.g., a person or an automated program or system) may use the CFD model 400 to optimize adjustable parameters 150, which include the NWGI parameters 152, according to the designed-for process variable. In other words, the user can use the CFD model 400 to explore different chamber designs via the sets of parameter values of the adjustable parameter 150. For example, the CFD model 400 can be used to measure and output etch byproduct removal rates at different locations based on a set of parameter values of the adjustable parameters 150, such as the wafer center (r=0) or the wafer edge (e.g., r=R). Simulations can be run until a set of parameter values is identified having an optimal process variable outcome that is within a target specification. The NWGI unit may then be designed and manufactured to have the set of parameter values. This set of parameter values may include values such as a diameter of the NWGI unit, a number of orifices (holes) through which gas flows from the NWIG unit onto a wafer (or other substrate), a diameter of these orifices, a spacing between these orifices, physical dimensions of the NWGI unit (height, width, or the like), an angle at which the orifices are set compared to the wafer, or other parameters as described herein or other suitable, designable parameters of the NWG unit.

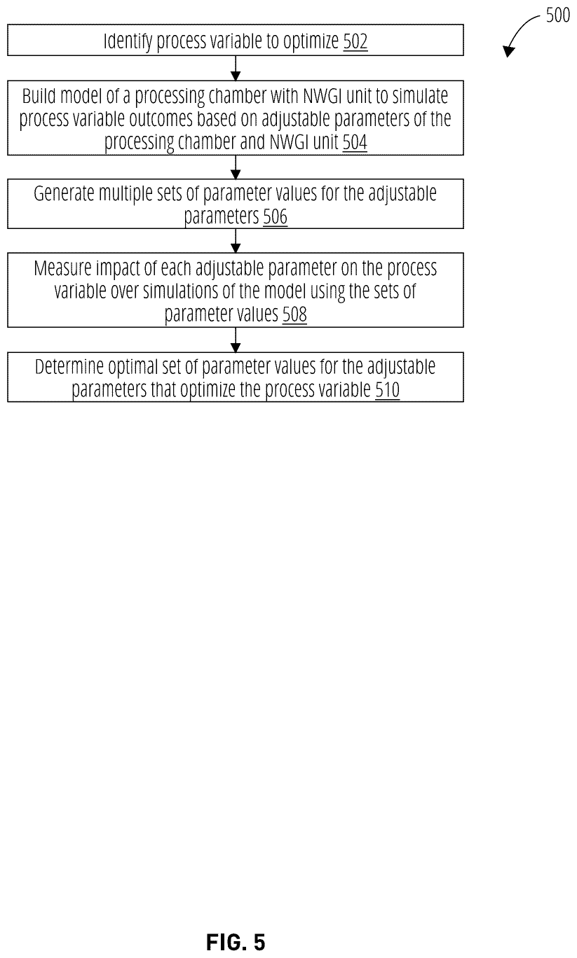

FIG. 5 is a flowchart of a method 500 of optimizing a process variable, according to one embodiment. The method 500 may be performed by processing logic that may comprise hardware (e.g., circuitry, dedicated logic, programmable logic, microcode, etc.), software (e.g., instructions run on a processing device to perform hardware simulation), firmware, or a combination thereof. In at least one embodiment, the processing logic may refer to one or more components of a larger system, such as the system 100. The processing logic may include one or more processors and one or more memory devices storing instructions that, when executed by the one or more processors, perform the method 500. The method 500 can be performed at least partially by other devices described herein.

At block 502, the processing logic may identify a process variable to optimize. This process variable may correspond to the processing of a substrate (e.g., a wafer) within a processing chamber including a near wafer gas injection (NWGI) unit, such as the NWGI unit 200 as described herein. In one embodiment, the process variable is a byproduct removal rate. In another embodiment, the process variable is an ion flux impinging rate or another variable related to extreme edge control (EEC).

At block 504, the processing logic may build a model of the processing chamber with the NWGI unit. This model may be used to simulate process variable outcomes based on adjustable parameters of the processing chamber and the NWGI unit (adjustable parameters 150). This model may be a CFD model or a physics-based digital twin model, as described herein. This model may be a different model that is capable of simulating process conditions within a processing chamber.

At block 506, the processing logic may generate multiple sets of parameter values for the adjustable parameters. Each of these sets of parameter values may be used by the model to perform a simulation of process conditions within the processing chamber. Each different set of parameter values may correspond to different simulated process conditions.

At block 508, the processing logic may measure or otherwise determine an impact that each adjustable parameter has on the process variable. The processing logic may determine this impact by comparing the simulations outcomes (process variable outcomes 154) to the sets of parameter values. In one embodiment, the processing logic may use the sets of parameter values and the simulation outcomes to train a machine learning model, which is able to determine relationships between each of the adjustable parameters and the simulation outcomes. These relationships may be represented by internal weights of the machine learning model. In some embodiments, the processing logic may use another type of model, such as a heuristic model or rule-based model, to determine the impact of the adjustable parameters on the process variable.

At block 510, the processing logic may determine an optimal set of parameter values for the adjustable parameters that optimize the process variable. The processing logic may determine the optimal set of parameter values based on the impact that each adjustable parameter has on the process variable. In embodiments where the process variable is the byproduct removal rate, the optimal set of parameter values may maximize the byproduct removal rate.

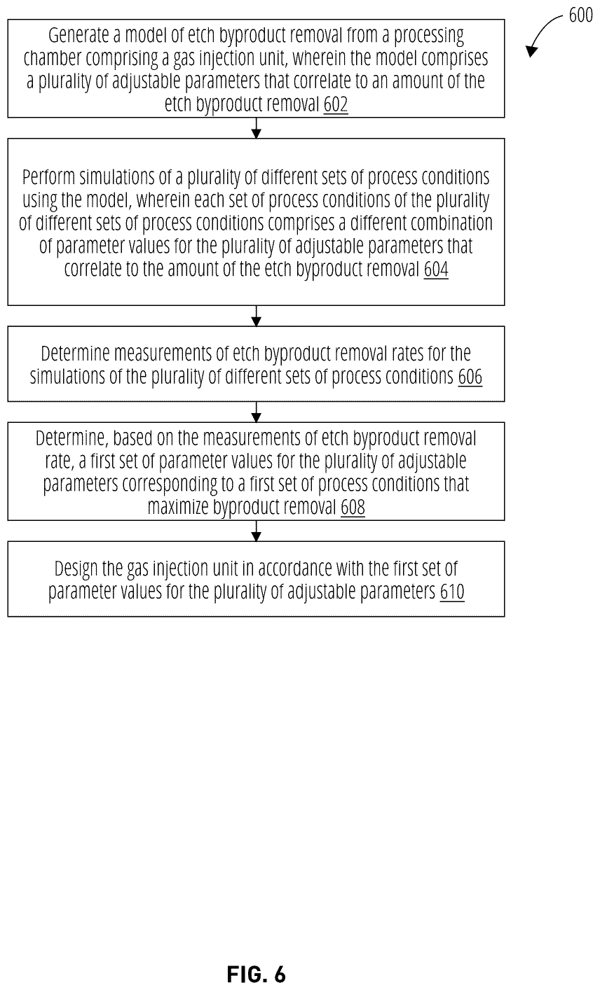

FIG. 6 is a flowchart of a method 600 of designing a gas injection unit (e.g., NWGI unit) to maximize an etch byproduct removal rate, according to one embodiment. The method 600 may be performed by processing logic that may comprise hardware (e.g., circuitry, dedicated logic, programmable logic, microcode, etc.), software (e.g., instructions run on a processing device to perform hardware simulation), firmware, or a combination thereof. In at least one embodiment, the processing logic may refer to one or more components of a larger system, such as the system 100. The processing logic may include one or more processors and one or more memory devices storing instructions that, when executed by the one or more processors, perform the method 600. The method 600 can be performed at least partially by other devices described herein.

At block 602, the processing logic may generate a model of etch byproduct removal from a processing chamber comprising a gas injection unit, wherein the model comprises a plurality of adjustable parameters that correlate to an amount of the etch byproduct removal.

At block 604, the processing logic may perform simulations of a plurality of different sets of process conditions using the model, wherein each set of process conditions of the plurality of different sets of process conditions comprises a different combination of parameter values for the plurality of adjustable parameters that correlate to the amount of the etch byproduct removal.

At block 606, the processing logic may determine measurements of etch byproduct removal rates for the simulations of the plurality of different sets of process conditions.

At block 608, the processing logic may determine, based on the measurements of etch byproduct removal rate, a first set of parameter values for the plurality of adjustable parameters corresponding to a first set of process conditions that maximize byproduct removal.

At block 610, the processing logic may design the gas injection unit in accordance with the first set of parameter values for the plurality of adjustable parameters. In some embodiments, designing the gas injection unit can include developing a model of the gas injection unit based on the first set of parameter values. This model may be developed in a digital setting, such as with CAD modelling. The designing of the gas injection unit may also include creating manufacturing drawings, planning manufacturing processes, and/or assembling a physical gas injection unit in accordance with the first set of parameter values.

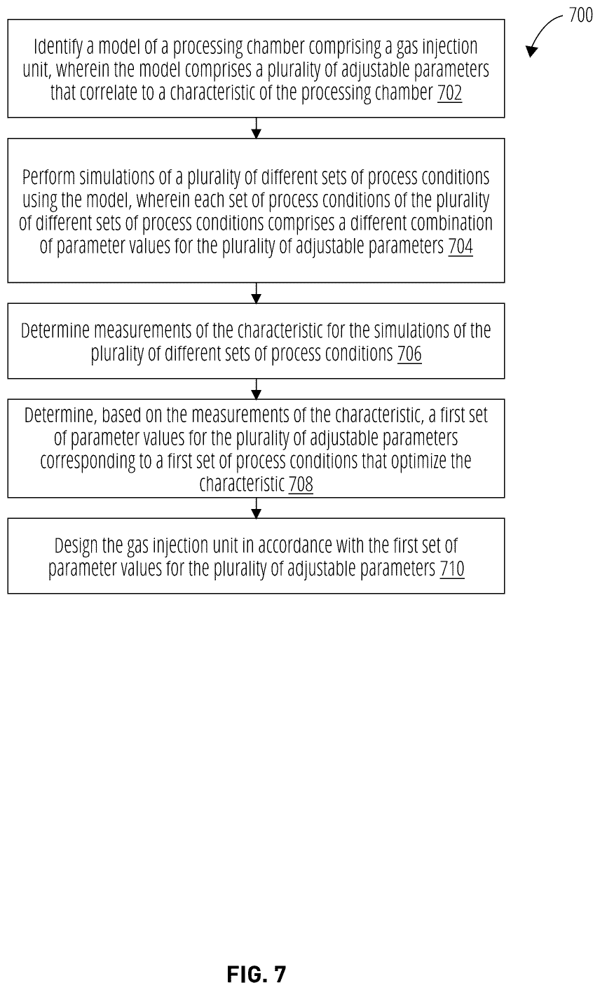

FIG. 7 is a flowchart of a method 700 of designing a gas injection unit (e.g., NWGI unit) to optimize a process variable, according to one embodiment. The method 700 may be performed by processing logic that may comprise hardware (e.g., circuitry, dedicated logic, programmable logic, microcode, etc.), software (e.g., instructions run on a processing device to perform hardware simulation), firmware, or a combination thereof. In at least one embodiment, the processing logic may refer to one or more components of a larger system, such as the system 100. The processing logic may include one or more processors and one or more memory devices storing instructions that, when executed by the one or more processors, perform the method 700. The method 700 can be performed at least partially by other devices described herein.

At block 702, the processing logic may identify a model of a processing chamber comprising a gas injection unit, wherein the model comprises a plurality of adjustable parameters that correlate to a characteristic of the processing chamber.

At block 704, the processing logic may perform simulations of a plurality of different sets of process conditions using the model, wherein each set of process conditions of the plurality of different sets of process conditions comprises a different combination of parameter values for the plurality of adjustable parameters.

At block 706, the processing logic may determine measurements of the characteristic for the simulations of the plurality of different sets of process conditions.

At block 708, the processing logic may determine, based on the measurements of the characteristic, a first set of parameter values for the plurality of adjustable parameters corresponding to a first set of process conditions that optimize the characteristic.

At block 710, the processing logic may design the gas injection unit in accordance with the first set of parameter values for the plurality of adjustable parameters. In some embodiments, designing the gas injection unit can include developing a model of the gas injection unit based on the first set of parameter values. This model may be developed in a digital setting, such as with CAD modelling. The designing of the gas injection unit may also include creating manufacturing drawings, planning manufacturing processes, and/or assembling a physical gas injection unit in accordance with the first set of parameter values.

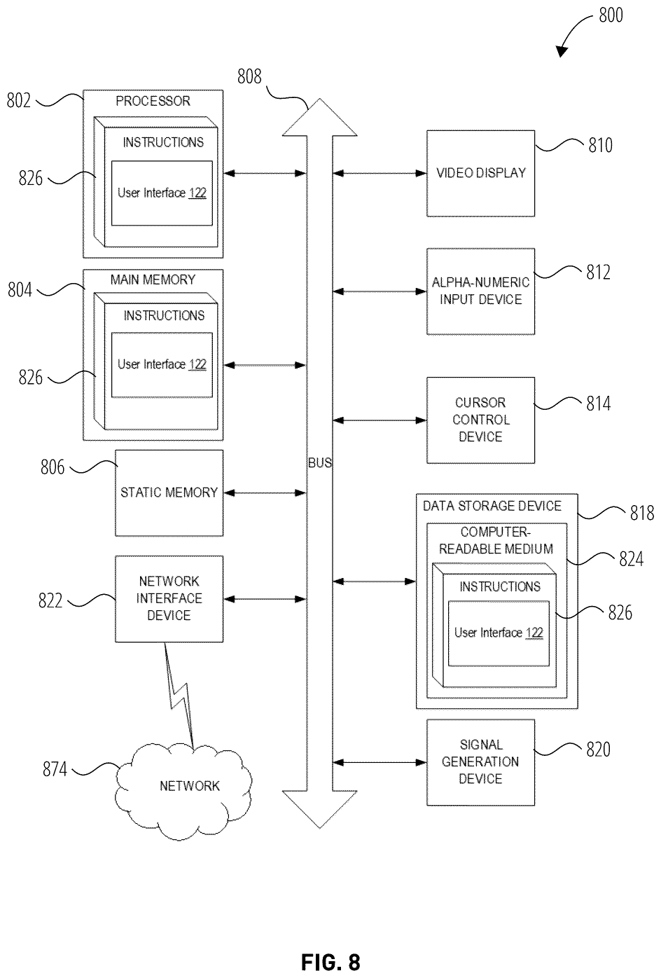

FIG. 8 is a block diagram illustrating a computer system 800, according to certain embodiments. In some embodiments, computer system 800 may be connected (e.g., via a network, such as a Local Area Network (LAN), an intranet, an extranet, or the Internet) to other computer systems. Computer system 800 may operate in the capacity of a server or a client computer in a client-server environment, or as a peer computer in a peer-to-peer or distributed network environment. Computer system 800 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein. In one embodiment, the computer system 800 may represent one or more portions of the system 100 as described above in FIG. 1. The computer system 800 may perform some or all operations corresponding to designing the near wafer gas injection (NWGI) unit 200 as described herein, including one or more of generating model(s) 190 to determine process variable outcomes 154 based on sets of parameter values of the adjustable parameters 150, generating model(s) 190 to determine relationships between the process variable outcomes 154 and the adjustable parameters 150 and determine an optimal set of parameter values (e.g., the first set of parameter values) for the adjustable parameters 150, or designing the NWGI unit 200 based on the optimal set of parameter values.

In a further aspect, the computer system 800 may include a processing device 802, a volatile memory 804 (e.g., Random Access Memory (RAM)), a non-volatile memory 806 (e.g., Read-Only Memory (ROM) or Electrically-Erasable Programmable ROM (EEPROM)), and a data storage device 818, which may communicate with each other via a bus 808.

Processing device 802 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 800 may further include a network interface device 822 (e.g., coupled to network 874). Computer system 800 also may include a video display unit 810 (e.g., an LCD), an alphanumeric input device 812 (e.g., a keyboard), a cursor control device 814 (e.g., a mouse), and a signal generation device 820.

In some embodiments, data storage device 818 may include a non-transitory computer-readable storage medium 824 (e.g., non-transitory machine-readable medium) on which may store instructions 826 encoding any one or more of the methods or functions described herein, including instructions encoding components of FIG. 1 (e.g., user interface 122, model 190, etc.) and for implementing methods described herein.

Instructions 826 may also reside, completely or partially, within volatile memory 804 and/or within processing device 802 during execution thereof by computer system 800, hence, volatile memory 804 and processing device 802 may also constitute machine-readable storage media.

While computer-readable storage medium 824 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general-purpose computer system selectively programmed by a computer program stored in the computer system. Such a computer program may be stored in a computer-readable tangible storage medium.

The methods and illustrative examples described herein are not inherently related to any particular computer or other apparatus. Various general-purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method comprising:
generating a model of etch byproduct removal from a processing chamber comprising a gas injection unit, wherein the model comprises a plurality of adjustable parameters that correlate to a rate of the etch byproduct removal;
performing simulations of a plurality of different sets of process conditions using the model, wherein each set of process conditions of the plurality of different sets of process conditions comprises a different combination of parameter values for the plurality of adjustable parameters that correlate to the rate of the etch byproduct removal;
determining measurements of etch byproduct removal rates for the simulations of the plurality of different sets of process conditions;
determining, based on the measurements of etch byproduct removal rate, a first set of parameter values for the plurality of adjustable parameters corresponding to a first set of process conditions that maximize byproduct removal; and
designing the gas injection unit in accordance with the first set of parameter values for the plurality of adjustable parameters.

2. The method of claim 1, wherein determining the measurements of the byproduct removal rate for the plurality of simulations comprises:
determining a first byproduct removal rate corresponding to a first simulation, the first simulation performed using a second set of parameter values of the plurality of parameters;
adjusting the plurality of parameters from the second set of parameter values to a third set of parameter values; and
determining a second byproduct removal rate corresponding to a second simulation, the second simulation performed using the third set of parameter values.

3. The method of claim 2, wherein determining the first set of parameter values comprises:
determining a relationship between byproduct removal and the plurality of parameters.

4. The method of claim 2, wherein adjusting the plurality of parameters from the first set of parameter values to the second set of parameter values comprises adjusting a center flow of one or more gases to the processing chamber.

5. The method of claim 2, wherein adjusting the plurality of parameters from the first set of parameter values to the second set of parameter values comprises adjusting a gas flow of the gas injection unit.

6. The method of claim 2, wherein adjusting the plurality of parameters from the first set of parameter values to the second set of parameter values comprises adjusting a pressure within the processing chamber.

7. The method of claim 2, wherein the gas injection unit comprises a plurality of orifices through which gas flows into the processing chamber, and wherein adjusting the plurality of parameters from the first set of parameter values to the second set of parameter values comprises adjusting a size of the plurality of orifices.

8. The method of claim 1, wherein, within the model, the gas injection unit is disposed within the processing chamber such that the gas injection unit is to direct gas onto a substrate being processed by the processing chamber during an etching process.

9. The method of claim 1, wherein the plurality of different sets of process conditions are based on a design of experiments (DoE).

10. The method of claim 1, wherein the model is a computational fluid dynamics (CFD) model.

11. A method comprising:
configuring a model of a processing chamber comprising a gas injection unit, wherein the model comprises a plurality of adjustable parameters that correlate to a variable of the processing chamber;
performing simulations of a plurality of different sets of process conditions using the model, wherein each set of process conditions of the plurality of different sets of process conditions comprises a different combination of parameter values for the plurality of adjustable parameters;
determining measurements of the variable for the simulations of the plurality of different sets of process conditions;
determining, based on the measurements of the variable, a first set of parameter values for the plurality of adjustable parameters corresponding to a first set of process conditions that optimize the variable; and
designing the gas injection unit in accordance with the first set of parameter values for the plurality of adjustable parameters.

12. The method of claim 11, wherein the variable is an etch byproduct removal rate, and wherein the first set of parameter values maximizes the etch byproduct removal rate.

13. The method of claim 11, wherein the variable is an extreme edge control (EEC) variable, and wherein the first set of parameters maximizes the EEC variable.

14. The method of claim 11, wherein the variable is an ion flux impinging rate, and wherein the first set of parameters enhances control over the ion flux impinging rate.

15. The method of claim 11, wherein determining the measurements of the variable for the plurality of simulations comprises:
determining a first variable outcome corresponding to a first simulation, the first simulation performed using a second set of parameter values of the plurality of parameters;
adjusting the plurality of parameters from the second set of parameter values to a third set of parameter values; and
determining a second variable outcome corresponding to a second simulation, the second simulation performed using the third set of parameter values.

16. A device comprising:
a processor; and
memory comprising instructions that, upon being executed by the processor, cause the device to:
configure a model of a processing chamber comprising a gas injection unit, wherein the model comprises a plurality of adjustable parameters that correlate to a variable of the processing chamber;
perform simulations of a plurality of different sets of process conditions using the model, wherein each set of process conditions of the plurality of different sets of process conditions comprises a different combination of parameter values for the plurality of adjustable parameters;
determine measurements of the variable for the simulations of the plurality of different sets of process conditions; and
determine, based on the measurements of the variable, a first set of parameter values for the plurality of adjustable parameters corresponding to a first set of process conditions that optimize the variable, wherein the gas injection unit is designed in accordance with the first set of parameter values.

17. The device of claim 16, wherein the variable is an etch byproduct removal rate, and wherein the first set of parameter values maximizes the etch byproduct removal rate.

18. The device of claim 16, wherein the variable is an extreme edge control (EEC) variable, and wherein the first set of parameters maximizes the EEC variable.

19. The device of claim 16, wherein the variable is an ion flux impinging rate, and wherein the first set of parameters enhances control over the ion flux impinging rate.

20. The device of claim 16, wherein to determine the measurements of the variable for the plurality of simulations, the instructions cause the device to:
determine a first variable outcome corresponding to a first simulation, the first simulation performed using a second set of parameter values of the plurality of parameters;
adjust the plurality of parameters from the second set of parameter values to a third set of parameter values; and
determine a second variable outcome corresponding to a second simulation, the second simulation performed using the third set of parameter values.
